(19) United States
(12) Patent Application Publication
(10) Pub. No.: US 2018/0166314 A1
(43) Pub. Date: Jun. 14, 2018

(54) Wafer Chuck Apparatus With Contractible Sealing Devices For Securing Warped Wafers

(71) Applicant: Ultratech, Inc., San Jose, CA (US)

(72) Inventors: Raymond Ellis, Aptos, CA (US); A.J. Crespin, San Jose, CA (US); Konrad Heinle, Livermore, CA (US); Charles Hu, Palo Alto, CA (US)

(21) Appl. No.: 15/834,718

(22) Filed: Dec. 7, 2017

Related U.S. Application Data
(60) Provisional application No. 62/431,790, filed on Dec. 8, 2016.

(51) Int. Cl. H01L 21/683; H01L 21/687

(52) U.S. Cl. CPC H01L 21/6838; H01L 21/68742; H01L 21/68735

(57) ABSTRACT

A wafer chuck apparatus includes a chuck with a body and a vacuum line system formed within the body. The wafer chuck apparatus has sealing devices each operably disposed in respective recesses formed in the body at an upper surface of the chuck. Each sealing device is contractible between an expanded operating position and a contracted operating position. The top end of each sealing device is configured to form a vacuum seal with a corresponding portion of a backside of a wafer. The sealing devices extend above the upper surface of the chuck higher than typical seals and guide the wafer down to the upper surface of the chuck where it can be engaged by vacuum features that chuck the wafer to the upper surface of the chuck. The sealing devices are particularly useful for chucking warped wafers.

### RELATED APPLICATION DATA

This application claims the benefit of priority of U.S. Provisional Patent Application Ser. No. 62/431,790, filed on Dec. 8, 2016, and titled “Wafer Chuck With Contractible Sealing Devices For Securing Warped Wafers,” which is incorporated by reference herein in its entirety.

### FIELD OF THE INVENTION

The present disclosure relates to chucks used to support wafers in semiconductor manufacturing, and in particular relates to a wafer chuck apparatus with contractible sealing devices for securing warped wafers.

### BACKGROUND

The manufacturing of semiconductor devices such as integrated circuit (IC) chips utilizes semiconductor wafers. The semiconductor wafers serve as a substrate in which the various three-dimension IC structures are formed using a series of process steps. Once the IC chips are formed, they then need to be packaged, i.e., encapsulated in a support structure to form the finalized IC device. More recently, semiconductor wafers and other types of large support wafers are finding increasing use in the packaging step, e.g., for fan-out wafer-level packaging, flip-chip packaging, and device packaging (e.g., of sensors and high-power devices such as lasers) using product wafers formed by interfacing a thin device wafer with a carrier wafer.

To perform lithography exposures either when fabricating the ICs or when packaging the ICs, the wafer must be held very flat. This requires holding the wafer down to a very flat surface using a vacuum. To this end, vacuum chucks have been developed to support wafers during lithography exposures.

With advances in semiconductor IC fabrication and packaging, the wafers are larger and tend to have larger amounts of warp. Unfortunately, when a wafer with a relatively large amount of warp is placed on a standard vacuum chuck, there can be too much leakage to generate the pressure differential necessary to pull the warped wafer down to the chuck surface.

### SUMMARY OF THE DISCLOSURE

An aspect of the disclosure is a wafer chuck apparatus for chucking a wafer having a backside. The wafer chuck apparatus includes: a chuck having a body and an upper surface, including at least one recess formed in the body at the upper surface, and a plurality of vacuum features open to the upper surface of the body; a vacuum line system formed within the body of the chuck and that is pneumatically connected to the vacuum features, to at least one recess, and to a vacuum pump; at least one sealing device operably disposed in the at least one recess and in pneumatic communication with the vacuum line system, wherein the at least one sealing device has a top end and is contractible between an expanded operating position and a contracted operating position, and wherein a sealing member defines the top end and is configured to form a vacuum seal with a portion of the backside of the wafer; and wherein the top end extends to a height H above the upper surface of the body of the chuck in the expanded operating position wherein the height H is in the range of 2 mm≤H≤6 mm, and wherein the at least one sealing device contracts from the expanded operating position to the contracted operating position wherein H=0 when the backside of the wafer is disposed upon and forms the vacuum seal with the at least one sealing device and the vacuum features.

Another aspect of the disclosure is the wafer chuck apparatus as described above, wherein the sealing member is resilient and contracts to a contracted state to define the contracted operating position.

Another aspect of the disclosure is the wafer chuck apparatus as described above, wherein the sealing member comprises a tubular bellows.

Another aspect of the disclosure is the wafer chuck apparatus as described above, wherein the tubular bellows has an interior and a bottom end, the recess includes a pillar with a top surface and a vacuum channel open at the top end of the at least one sealing device and pneumatically connected to the vacuum line system, and wherein the pillar extends into the interior of the tubular bellows from the bottom end of the tubular bellows, and wherein the top surface of the pillar is co-planar with the upper surface of the chuck.

Another aspect of the disclosure is the wafer chuck apparatus as described above, and further including: a support member that supports the sealing member; and a resilient member that supports the support member, wherein the resilient member has an extended state that defines the extended operating position and has a contracted state that defines the contracted operating position.

Another aspect of the disclosure is the wafer chuck apparatus as described above, wherein the recess includes a pillar with a top surface and a vacuum channel open at the top end of the at least one sealing device and pneumatically connected to the vacuum line system, and wherein the support member includes a central hole, wherein the pillar extends into the central hole of the support member, and wherein the top surface of the pillar is co-planar with the upper surface of the chuck.

Another aspect of the disclosure is the wafer chuck apparatus as described above, wherein the support member has a donut shape.

Another aspect of the disclosure is the wafer chuck apparatus as described above, wherein the sealing member comprises a gasket.

Another aspect of the disclosure is the wafer chuck apparatus as described above, wherein the sealing member comprises an O-ring.

Another aspect of the disclosure is the wafer chuck apparatus as described above, wherein at least one sealing device comprises three or more sealing devices.

Another aspect of the disclosure is the wafer chuck apparatus as described above, wherein the at least one sealing device comprises at least three and no more than twelve sealing devices.

Another aspect of the disclosure is a wafer chuck apparatus for chucking a wafer having a backside. The wafer chuck apparatus includes: a chuck having a body and an upper surface, including at least three recesses formed in the body at the upper surface, and a plurality of vacuum holes open to the upper surface of the body; a vacuum line system formed within the body of the chuck and that is pneumatically connected to the vacuum holes, to each of the recesses, and to a vacuum pump; at least three contractible sealing devices respectively operably disposed in the at least three recesses and in pneumatic communication with the vacuum line system, wherein each contractible sealing device has an expanded operating position and a contracted operating position and comprises: i) a top end that resides at a height H above the upper surface of the body of the chuck in the expanded operating position, wherein the height H is in the range of 2 mm≤H≤6 mm; ii) a sealing member that defines the top end and that is configured to form a localized vacuum seal with a portion of the backside of the wafer when the wafer is brought into contact with the sealing member; iii) a support member having opposite top and bottom surfaces, wherein the top surface supports the sealing member and wherein a vacuum channel passes through the support member and is in pneumatic communication with the vacuum line system; and iv) a resilient member in contact with the bottom surface of the support member also in contact with a bottom wall of the recesses, the resilient member being in an expanded state in the expanded operating position and a contracted state in the contracted operating position; and wherein each contractible sealing device is configured to move from the expanded operating position to the contracted operating position wherein H=0 when the wafer is disposed upon and supported by the at least three contractible sealing devices.

Another aspect of the disclosure is the wafer chuck apparatus as described above, wherein the sealing member comprises one of a gasket, an O-ring or a bellows.

Another aspect of the disclosure is the wafer chuck apparatus as described above, wherein the resilient member comprises as least one spring.

Another aspect of the disclosure is the wafer chuck apparatus as described above, wherein the sealing member has a central aperture, and wherein the recess includes a pillar with a top surface, with the vacuum channel passing through the pillar and open at the top end and pneumatically connected to the vacuum line system, and wherein the pillar extends into the central aperture of the sealing member.

Another aspect of the disclosure is the wafer chuck apparatus as described above, wherein the top surface of the pillar is co-planar with the upper surface of the chuck.

Another aspect of the disclosure is a method of chucking a wafer having a backside and a first amount of warp onto an upper surface of a chuck. The method includes: a) pneumatically engaging respective portions of the backside of the wafer with a plurality of contractible sealing devices that reside in respective recesses formed in the upper surface of the chuck and that initially extend above the upper surface of the chuck by an initial height H in the range of 2 mm≤H≤6 mm to cause the wafer to have a second amount of warp that is less than the first amount of warp; b) contracting the plurality of contractible sealing devices into their respective recesses to bring the wafer down to the upper surface of the chuck so that the height H=0; and c) pneumatically engaging the backside of the wafer at the upper surface of the chuck to cause the wafer to have a third amount of warp than is less than the second amount of warp.

Another aspect of the disclosure is the method as described above, wherein each contractible sealing device comprises a tubular bellows having an open top side that forms a vacuum seal with a corresponding one of the respective portions of the backside of the wafer in act a), and wherein the act b) of contracting includes compressing the tubular bellows.

Another aspect of the disclosure is the method as described above, wherein the plurality of contractible sealing devices comprises at least three and no more than twelve contractible sealing devices.

Another aspect of the disclosure is the method as described above, wherein each contractible sealing device includes a sealing member supported by a spring, and wherein the act b) of contracting includes compressing the spring.

Another aspect of the disclosure is the method as described above, wherein a support member resides between the sealing member and the spring.

Another aspect of the disclosure is the method as described above, wherein the wafer has a weight, and wherein the act b) of contracting is caused by the weight of the wafer.

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description explain principles and operation of the various embodiments. As such, the disclosure will become more fully understood from the following Detailed Description, taken in conjunction with the accompanying Figures, in which:

FIG. 1A is a top-down view of an example chuck apparatus as disclosed herein;

FIG. 1B is a side view of the chuck apparatus of FIG. 1A shown along with a wafer in the process of being chucked of the chuck apparatus;

FIGS. 2A and 2B are schematic diagrams of a generalized embodiment of the contractible sealing device in an extended (non-contracted) operating state (FIG. 2A) and in a contracted operating state (FIG. 2B).

FIGS. 3A and 3B are close-up cross-sectional views of a portion of the chuck that shows the generalized embodiment of the contractible sealing device of FIGS. 2A and 2B, wherein the two views illustrate the two operational states for the contractible sealing device;

FIGS. 4A through 4C are close-up cross-sectional views of a portion of the chuck that shows details of a first example embodiment of a contractible sealing device as disclosed herein, wherein the three views show the two operational states for the contractible sealing device;

FIGS. 5A through 5C are close-up cross-sectional views of a portion of the chuck that shows details of a second example embodiment of a contractible sealing device as disclosed herein, wherein the three views show three operational states for the contractible sealing device;

FIG. 6 is a top-down view of an example recess formed in the chuck and that includes a central pillar having a vacuum channel formed therein;

FIG. 7A is a top-down view and FIG. 7B is a top elevated view of an example support member that has a donut shape, wherein the central hole is sized to accommodate the central pillar of the recess shown in FIG. 6;

FIGS. 8A through 8C are close-up cross-sectional views of a portion of the chuck that shows details of a third example embodiment of a contractible sealing device as disclosed herein, wherein the three views show three operational states for the contractible sealing device; and

FIGS. 9A and 9B are side elevated and x-z cross-sectional views, respectively, of an example sealing member in the form of tubular bellows.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

Cartesian coordinates are shown in some of the Figures for the sake of reference and are not intended to be limiting as to direction or orientation.

The term “chucking” is used herein to refer to the act of placing and securing a wafer onto the upper surface of a chuck.

Chuck Apparatus

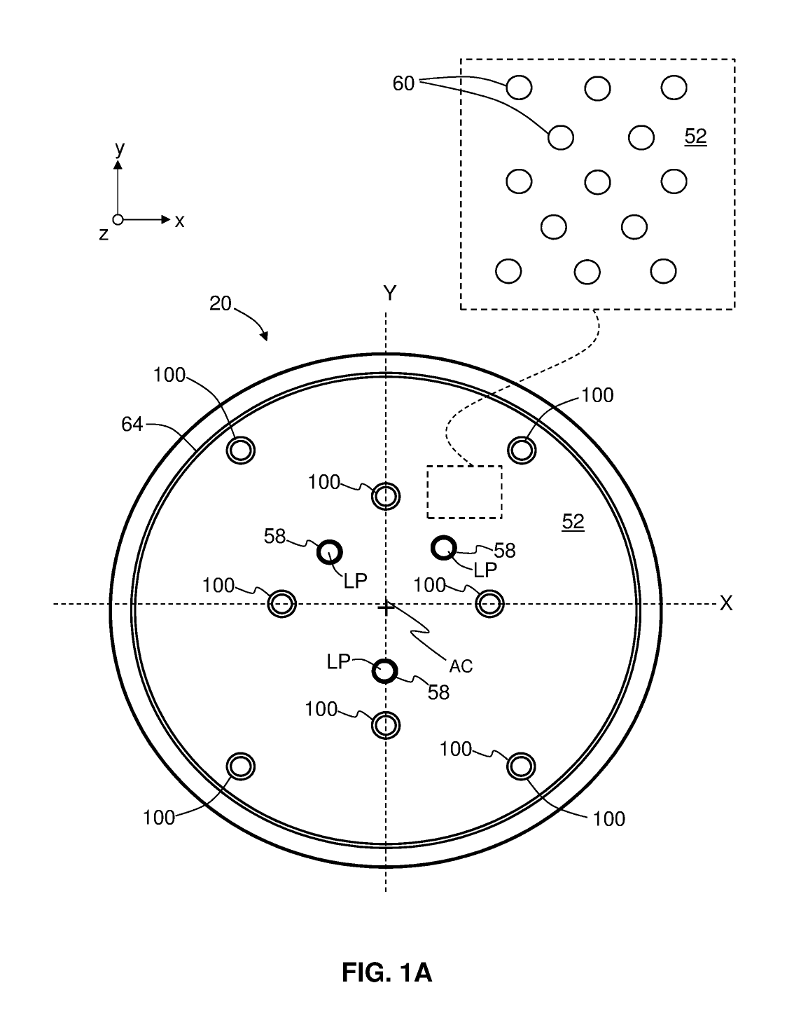

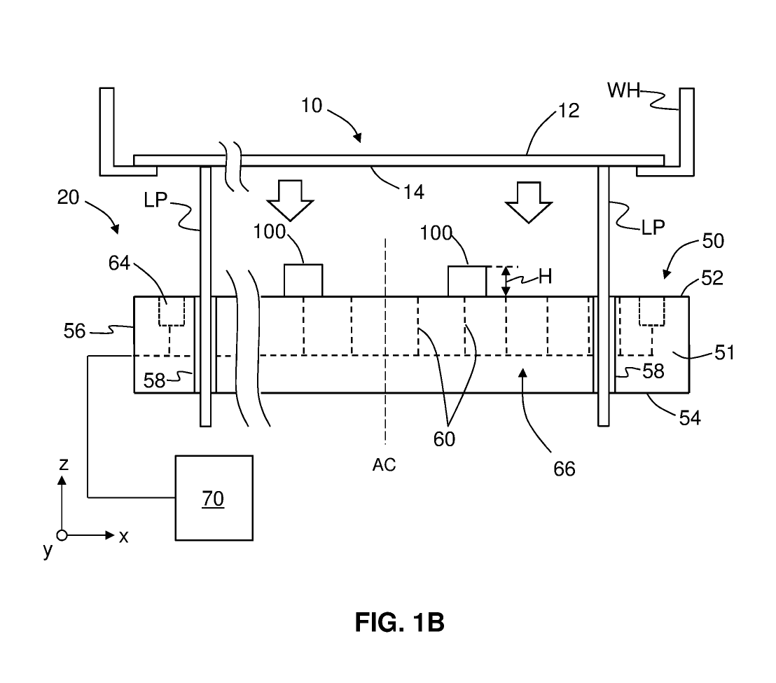

FIG. 1A is a top-down view of an example chuck apparatus 20 as disclosed herein. FIG. 1B is a side view of chuck apparatus 20 of FIG. 1A shown along with a wafer 10 that has a topside 12 and a backside 14. Chuck apparatus 20 includes a chuck 50 that has a chuck body 51, an upper surface 52, a lower surface 54 and a perimeter 56. Chuck 50 also has a central axis AC that runs through the center of the chuck 50 in the z-direction. Chuck 50 supports at least one contractible sealing device (“sealing device”) 100 within the chuck body 51 and adjacent to upper surface 52, as described in greater detail below. Each sealing device 100 can extend above upper surface 52 of chuck 50 by a height H, which in an example is in the range from 2 mm to 6 mm, when the sealing device is in its extended (i.e., uncontracted) operating position. In an example, chuck 50 includes at least three sealing devices 100. In another example, chuck 50 includes at least three but no more than twelve sealing devices 100.

Chuck 50 also includes a plurality of vacuum features 60 (see close-up inset of FIG. 1A) that are open at upper surface 52 and that are connected by a vacuum line system 66 to a vacuum pump 70. In an example, vacuum features 60 comprise holes, grooves, rings or the like that communicate a vacuum to upper surface 52 of chuck 50. Chuck 50 includes a vacuum ring 64 formed in upper surface 52 and that resides in proximity to perimeter 56. Vacuum ring 64 is configured to create a seal between backside 14 of wafer 10 and upper surface 52, so that when wafer 10 is pulled down, it will maintain a low pressure that forces the wafer flat. Vacuum ring 64 is also connected to vacuum pump 70 by vacuum line system 66. Each sealing device 100 is pneumatically connected to the vacuum pump 70 by vacuum line system 66.

In an example, chuck apparatus 20 includes apparatus for supporting and handling (moving) wafer 10, such as lift pins LP that pass through holes 58 in the chuck body 51 and that movably support wafer 10. In another example, a wafer handler WH is used to handle and move wafer 10. In other Figures, the apparatus for supporting and handling wafer 10 is omitted from the Figures for ease of illustration.

Wafer 10 has a first amount of warp associated with the wafer being in the free state, i.e., not mounted to a surface or otherwise engaged by any devices other than a wafer support and handling apparatus. Thus, in an initial phase as wafer 10 is being provided to the chuck apparatus 20 but before being engaged thereby, the wafer is in its most warped state. The amount of warp can be characterized using a variety of known techniques. One technique includes measuring a peak-to-valley variation of the wafer topography relative to a flat reference surface. In an example, the topography can be measured relative to one of the wafer surfaces or a median surface that lies between topside 12 and backside 14.

Sealing devices 100 facilitate chucking warped wafer 10 by reaching up from upper surface 52 of chuck 50 by the height H and pneumatically engaging respective portions of backside 14 of the wafer before it comes under the influence of the vacuum features 60. This defines an intermediate chucking phase where wafer 10 is engaged by chuck 50 of chuck apparatus 20. At this point, wafer 10 has a second amount of warp that is less than the first amount of warp. This reduction in warp is accomplished by sealing devices 100 pulling down on wafer 10 at different locations. In an example, the locations of sealing devices 100 are chosen to be reasonably spread out over upper surface 52 of chuck 50, such as shown in the example configuration of FIG. 1A.

Then, when wafer 10 is brought down to upper surface 52 of chuck 50, the reduced second amount of warp facilitates the final chucking of the wafer to the upper surface of the chuck using the vacuum features 60. In the final chucking phase, wafer 10 has a third amount of warp that is less than the second amount of warp.

This chucking method provides for more secure chucking of a warped wafer 10 than if the warped wafer is provided directly to upper surface 52 of chuck 50 without the intermediate chucking phase that employs sealing devices 100 disclosed herein.

### Generalized Embodiment

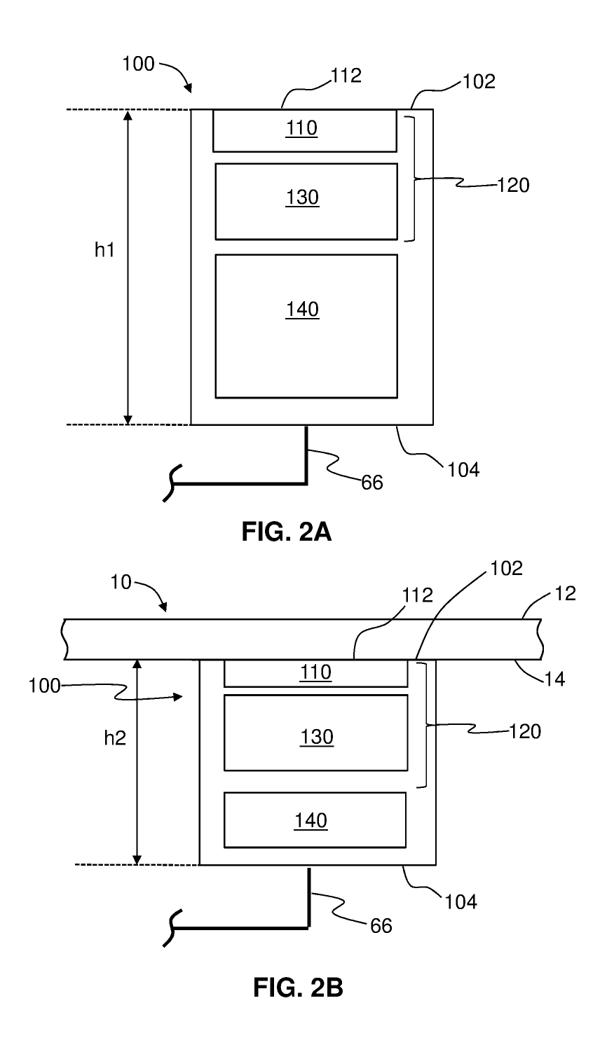

FIGS. 2A and 2B are schematic diagrams of a generalized embodiment of sealing device 100 in two different operating positions, namely an extended operating position (FIG. 2A) and a contracted operating position (FIG. 2B). Sealing device 100 has an upper end 102 and a lower end 104. Sealing device 100 has a height h1 in the extended operating position as measured between upper end 102 and lower end 104. Sealing device 100 also has a height h2 in the contracted operating position also measured from the upper end 102 to the lower end 104, where h1>h2. Sealing device 100 is pneumatically coupled to vacuum pump 70 (FIG. 1B) via vacuum line system 66 as discussed above.

Sealing device 100 includes at least one sealing member 110 that has a top end 112 that defines upper end 102 of the sealing device. Thus, top end 112 of sealing member 110 is capable of forming a vacuum seal with backside 14 of wafer 10 when the wafer and sealing device 100 are brought into contact, as shown in FIG. 2B. In an example, sealing device 100 is contractible by virtue of sealing member 110 being able to expand and contract.

In an example, sealing device 100 also optionally includes a support member 130 that supports sealing member 110 to define a sealing assembly 120. In an example, sealing assembly 120 is mechanically connected to a resilient member 140 that expands and contracts to make sealing device 100 contractible or even more contractible. In an example, both sealing member 110 and resilient member 140 can expand and contract.

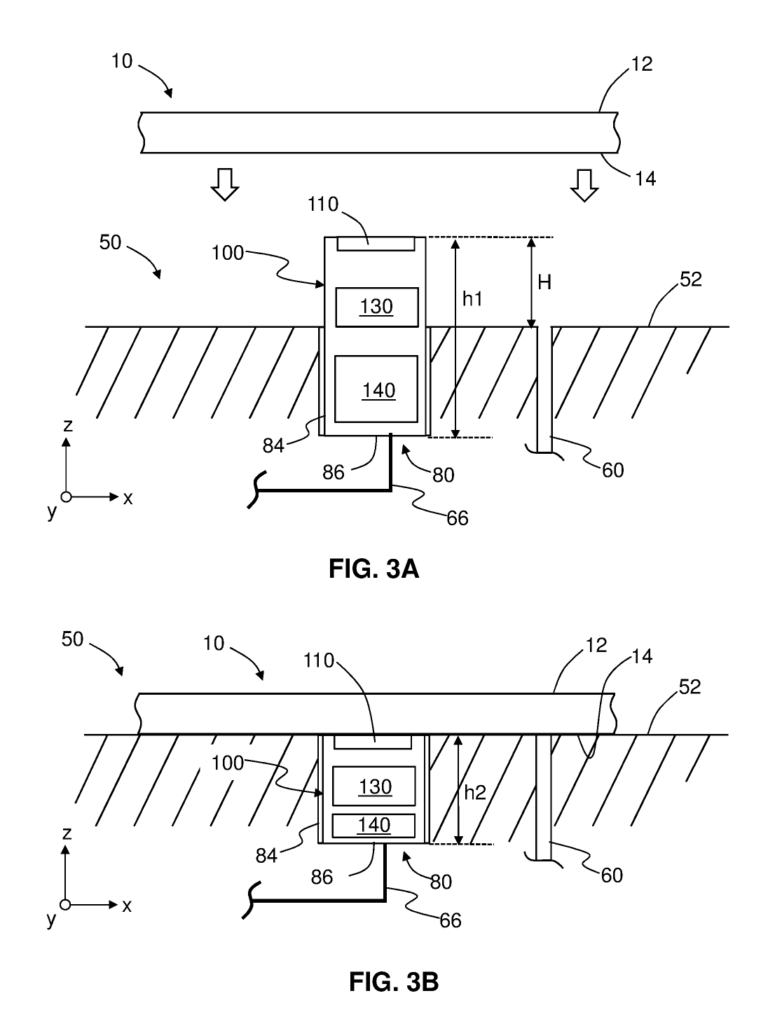

FIGS. 3A and 3B are close-up x-z cross-sectional views of a portion of chuck 50 showing a generalized embodiment of sealing device 100 in two different operating positions, namely the extended operating position (FIG. 3A) and the contracted operating position (FIG. 3B). Sealing device 100 is disposed in a recess 80 formed in chuck body 51 at upper surface 52 of chuck 50. Recess 80 has sidewalls 84 and a bottom wall 86. Recess 80 can have different configurations as described below. Sealing device 100 is thus contractible within recess 80 as shown in FIGS. 3A and 3B and as described in greater detail below.

### First Example Embodiment

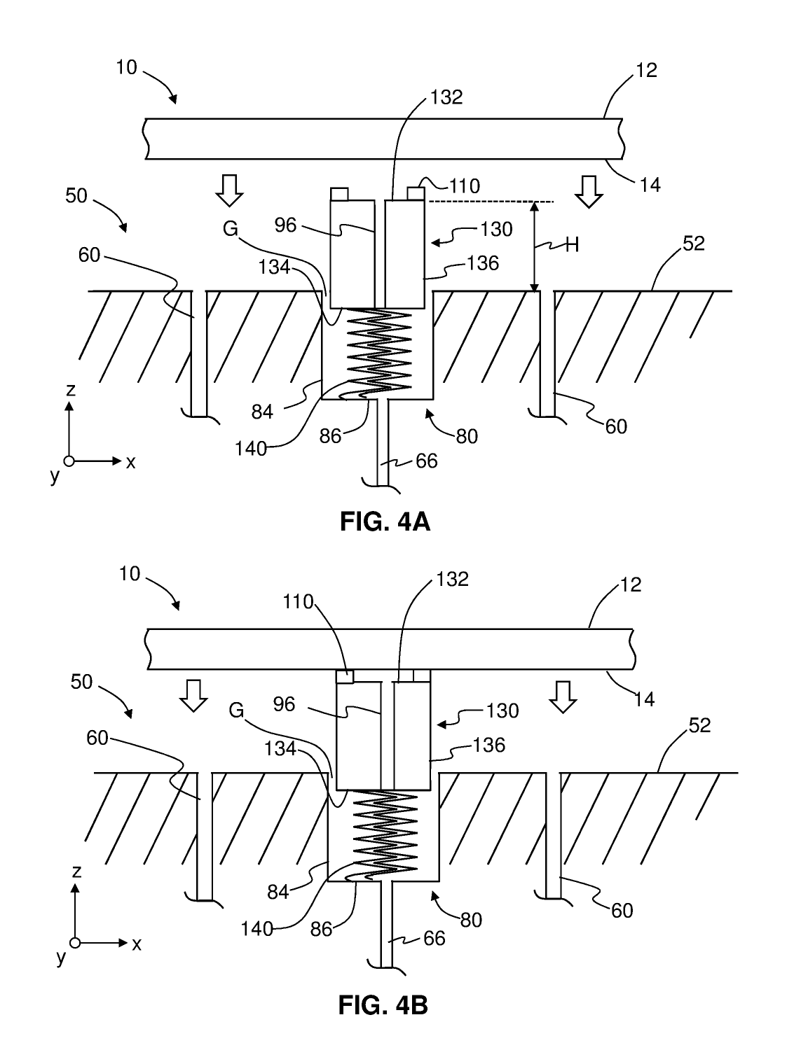

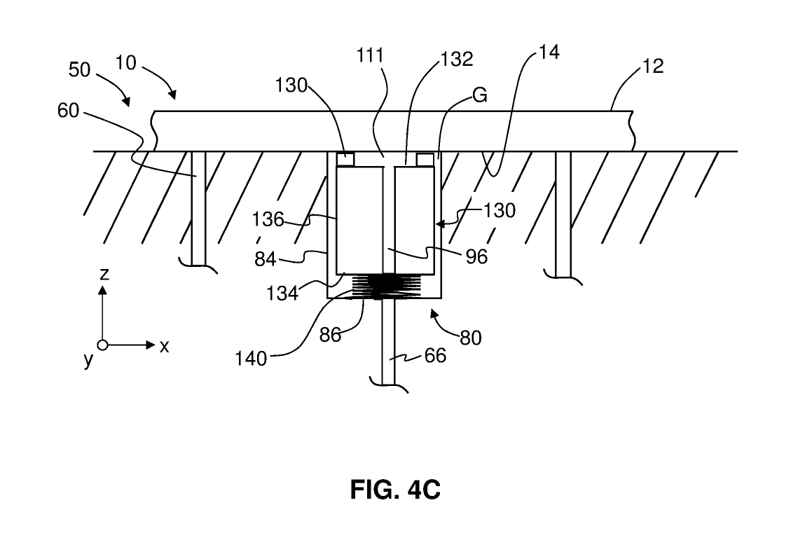

FIGS. 4A through 4C are close-up x-z cross-sectional views of chuck 50 showing the details of a first example embodiment of sealing device 100 in the two different operating positions.

Sealing device 100 of FIGS. 4A through 4C show an example support member 130. Support member 130 has a top surface 132 and a bottom surface 134 and a perimeter 136. Support member 130 is sized to fit closely within recess 80 and in an example has the same general cylindrical shape as the recess. In an example, support member 130 is monolithic. In an example, there can be a small gap G between sidewall 84 of recess 80 and perimeter 136 of support member 130 (the size of gap G is exaggerated in the Figures for clarity). A vacuum channel 96 runs between top surface 132 and bottom surface 134. Top surface 132 supports sealing member 110. In an example, sealing member 110 can be in the form of a gasket, e.g., rubber gasket or O-ring.

Support member 130 is supported at bottom surface 134 by a resilient member 140, which can be in the form of a spring or a material that can be compressed when subjected to a compressive force and that can also expand when the compressive force is removed. In an example, resilient member 140 does not substantially block vacuum channel 96 at bottom surface 134. Support member 130 is movable in the z-direction within recess 80 by the expansion and contraction of resilient member 140.

With reference to FIG. 4A, support member 130 extends above upper surface 52 of chuck 50 by height H in anticipation of receiving wafer 10. Since wafer 10 is still not yet in contact with sealing device 100, resilient member 140 is in its extended position (i.e., is in an extended state) within recess 80. Meanwhile, vacuum pump 70 is operating to pull a vacuum through vacuum line system 66, which as noted above is pneumatically connected to recess 80. Thus, there is a vacuum at top surface 132 of support member 130 via vacuum channel 96, which is pneumatically connected to vacuum line system 66 through recess 80. The amount of vacuum pulled via vacuum channel 96 is preferably much larger than that at gap G. This can be accomplished by making the cross-sectional area of vacuum channel 96 substantially larger than the cross-sectional area of gap G. In FIG. 4A, sealing device 100 is in the extended position at its maximum height H.

With reference now to FIG. 4B, wafer 10 is then lowered onto the plurality of sealing devices 100 of chuck 50, e.g., through the use of the aforementioned wafer support and handling apparatus. In an example, at least three sealing devices 100 are employed. In the example of FIG. 1A, eight sealing devices 100 are employed. Each sealing device 100 receives a corresponding portion of backside 14 of wafer 10 at sealing member 110. Backside 14 of wafer 10 is then sealed to each sealing member 110 by the vacuum provided by vacuum channel 96, thereby forming in each sealing member 110 a localized low-pressure sealed region 111 defined by backside 14 of wafer 10, sealing member 110 and top surface 132 of support member 130. At this point in the process, wafer 10 can still be substantially supported by the wafer support and handling apparatus.

With reference now to FIG. 4C, once wafer 10 is secured to sealing devices 100, the wafer then lowered onto upper surface 52 of chuck 50, e.g., by allowing more of the weight of the wafer to rest upon the sealing devices. This can be done simply by controlled lowering of wafer 10 using the wafer handler. During this time, resilient member 140 is compressed and placed in a contracted state by the local low pressure in recess 80 so that support member 130 moves lower into the recess. Sealing devices 100, which are now engaged with backside 14 of wafer 10, guide the wafer down to upper surface 52 of chuck 50. Vacuum features 60 further engage respective portions of backside 14 of wafer 10 to hold the wafer onto upper surface 52 of chuck 50. In FIG. 4C, sealing device 100 is in its contracted position wherein H=0.

Thus, in a first stage, sealing devices 100 engage respective portions of backside 14 of wafer 10 while the wafer is still outside of the vacuum range of vacuum features 60 and while the sealing devices are in their extended operating position. In a second stage, sealing devices 100 are used to control the landing of wafer 10 onto upper surface 52 of chuck 50 so that in the third stage the full vacuum of vacuum line system 66 can be employed to chuck the wafer via vacuum features 60. Sealing devices 100 are relative tall, i.e., they reach to a height H above upper surface 52 of chuck 50 that is higher than conventional ring seals. In the third stage, sealing devices 100 are in their contracted operating positions.

### Second Embodiment

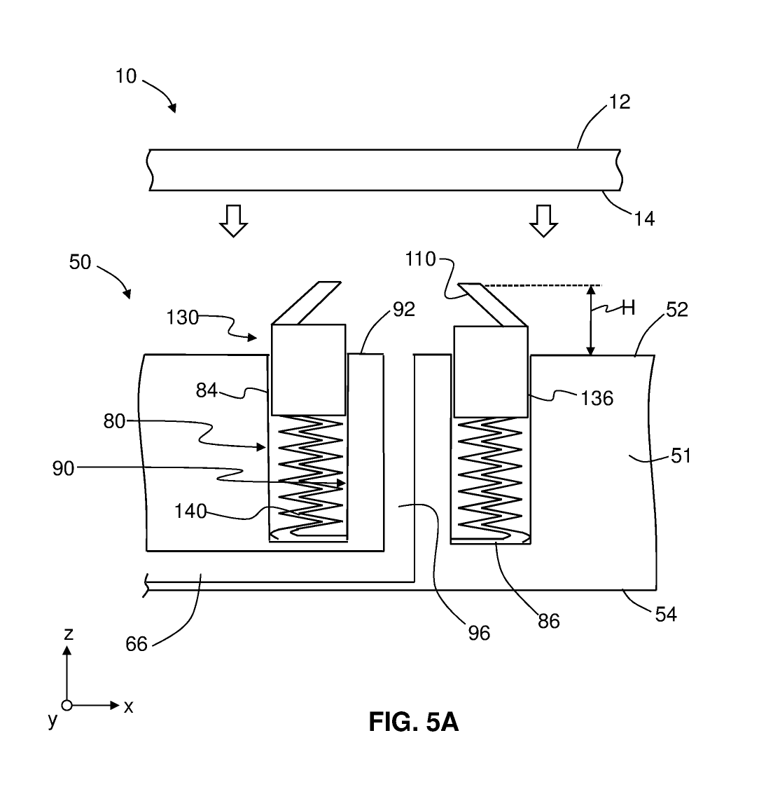

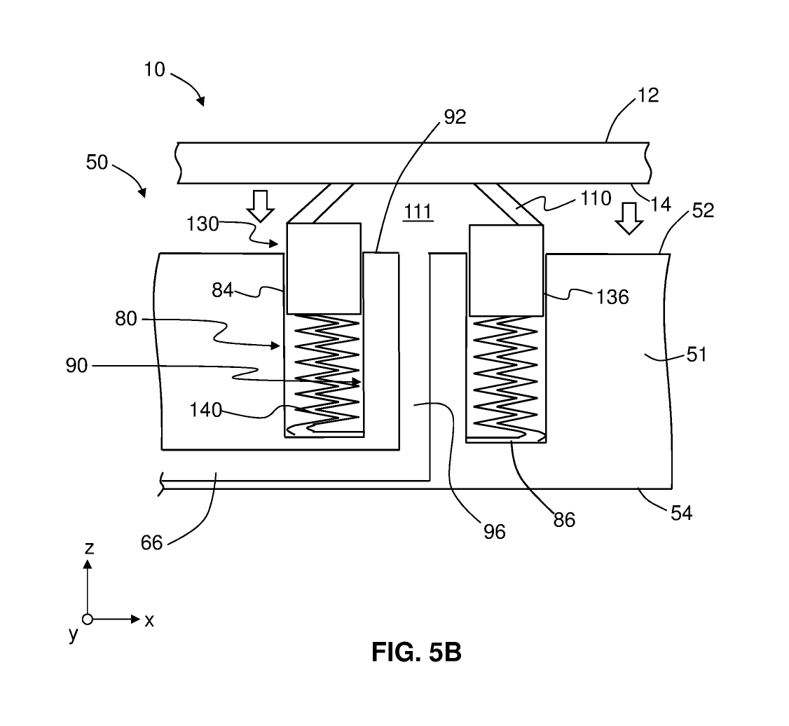

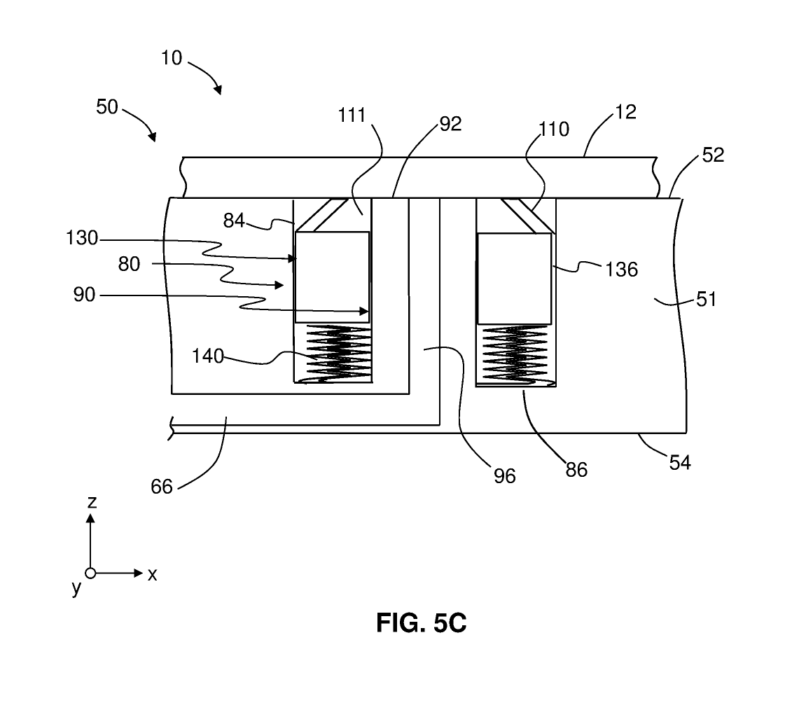

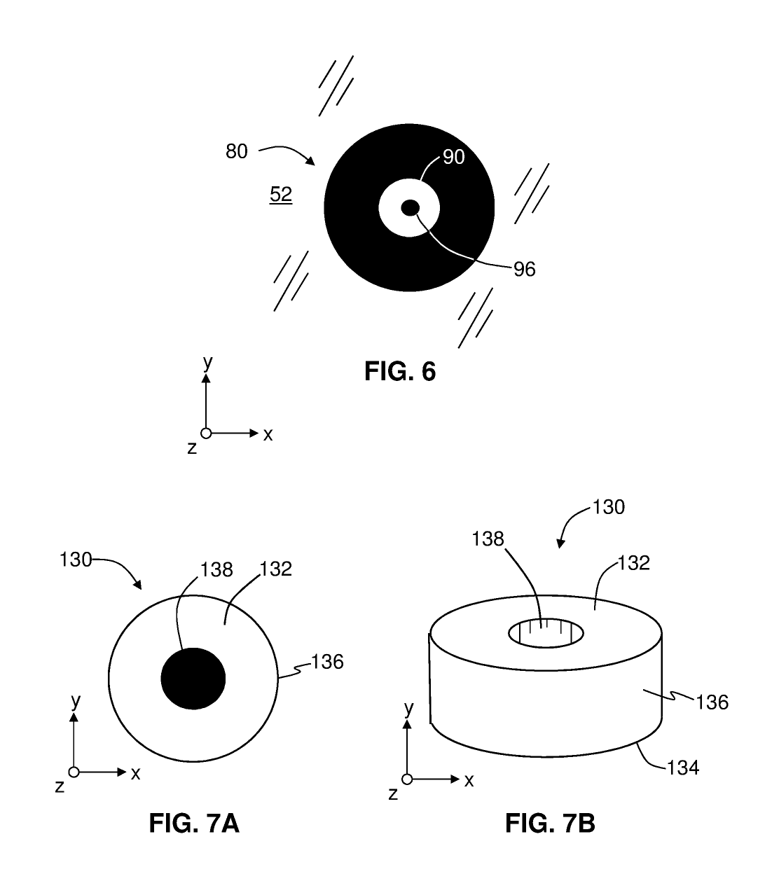

FIGS. 5A through 5C are close-up x-z cross-sectional views of chuck 50 showing the details of a second example embodiment of sealing device 100 in two different operating positions. Sealing device 100 of FIGS. 5A through 5C is similar that shown in FIGS. 4A through 4C but includes a central pillar 90 within recess 80, as best seen in the top-down view of FIG. 6. Vacuum channel 96 runs in the z-direction through central pillar 90 and connects to vacuum line system 66 within chuck body 51. Central pillar 90 has a top surface 92 that in an example resides in the plane of upper surface 52 of chuck 50.

FIGS. 7A and 7B are top-down and top-elevated views, respectively, of an example support member 130 that has a donut shape with a central hole 138 sized to accommodate central pillar 90 so that support member 130 can be disposed within recess 80, with the central pillar extending into central hole 138. Resilient member 140 can also have a donut shape or can comprise a plurality of separate resilient elements.

With reference again to FIG. 5A, support member 130 extends above upper surface 52 of chuck 50 in anticipation of receiving wafer 10. Since wafer 10 is still not yet in contact with sealing device 100, resilient member 140 is in an extended position (i.e., is in an extended state) within recess 80. Meanwhile, vacuum pump 70 is operating to pull a vacuum through vacuum line system 66, which as noted above is pneumatically connected to vacuum channel 96 of central pillar 90. Thus, there is a vacuum at top surface 132 of support member 130 via vacuum channel 96. In FIG. 5A, sealing device 100 is in the extended position at its maximum height H.

With reference now to FIG. 5B, wafer 10 is then lowered onto the plurality of sealing devices 100 of chuck 50, e.g., through the use of the aforementioned wafer support and handling apparatus. In an example, at least three sealing devices 100 are employed. Each sealing device 100 receives a respective portion of backside 14 of wafer 10 at sealing member 110. Backside 14 of wafer 10 is then sealed to sealing member 110 by the vacuum provided by vacuum channel 96, thereby forming localized low-pressure sealed region 111. In the present example embodiment, localized low-pressure sealed region 111 is defined by backside 14 of wafer 10, sealing member 110 and top surface 132 of support member 130. At this point in the process, wafer 10 can still be substantially supported by the wafer support and handling apparatus.

With reference now to FIG. 5C, once wafer 10 is secured to sealing devices 100, the wafer is then lowered onto upper surface 52 of chuck 50, e.g., by allowing more of the weight of the wafer to rest upon the sealing devices. This can be done simply by controlled lowering of wafer 10. During this time, resilient member 140 compresses so that support member 130 moves lower into recess 80. Sealing devices 100, which are now engaged with respective portions of backside 14 of wafer 10, help guide the wafer down to upper surface 52 of chuck 50. Vacuum features 60 (FIG. 1A) further engage respective portions backside 14 of wafer 10 to hold the wafer onto upper surface 52 of chuck 50. Note that top surface 92 of central pillar 90 also supports backside 14 of wafer 10. In FIG. 5C, sealing device 100 is shown in its contracted operating position.

Thus, as in the first embodiment, in the first stage, sealing devices 100 engage the backside 14 of wafer 10 while the wafer is still outside of the vacuum range provided by vacuum features 60 and while sealing devices 100 are in their extended operating position. In the second stage, sealing devices 100 are used to control the landing of wafer 10 onto upper surface 52 of chuck 50. In the third stage, the full vacuum of vacuum line system 66 is employed to chuck wafer 10 via vacuum features 60. Localized low-pressure sealed regions 111 defined by sealing devices 100 reach higher above upper surface 52 of chuck 50 than conventional ring seals. In the third stage, sealing devices 100 are in their contracted operating positions wherein H=0.

### Third Embodiment

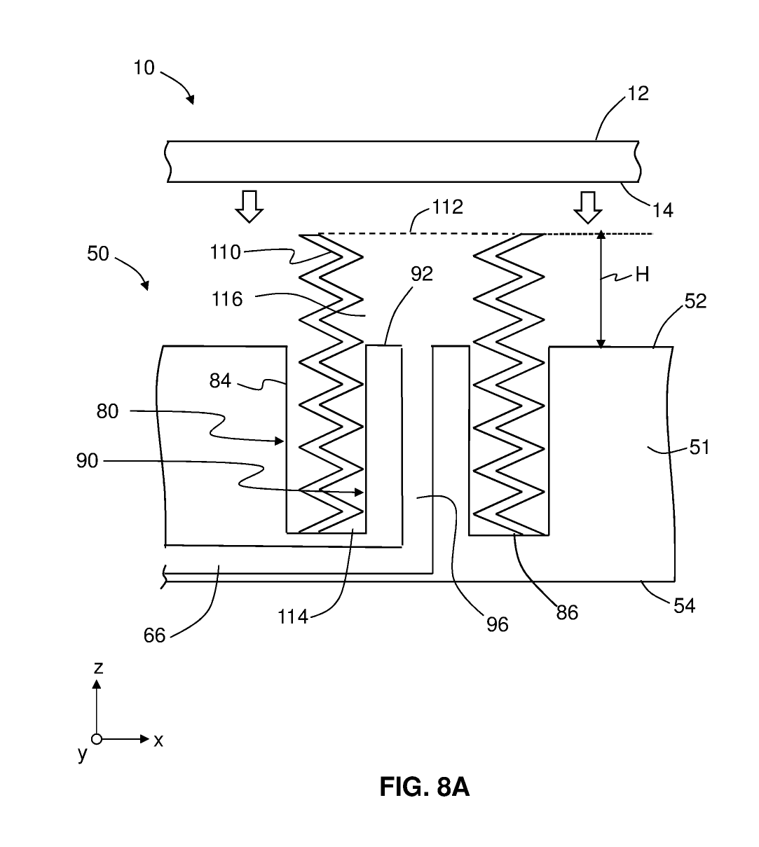

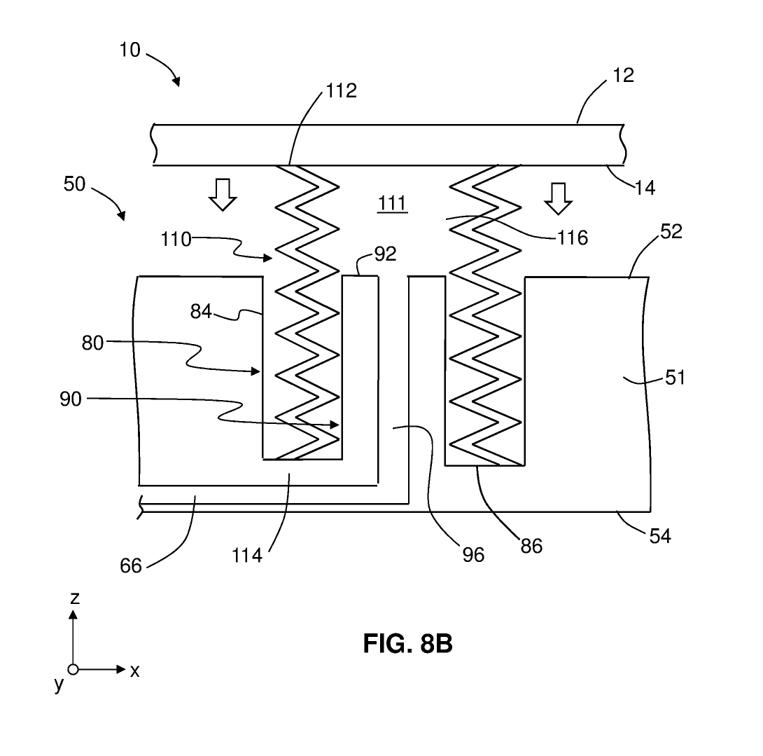

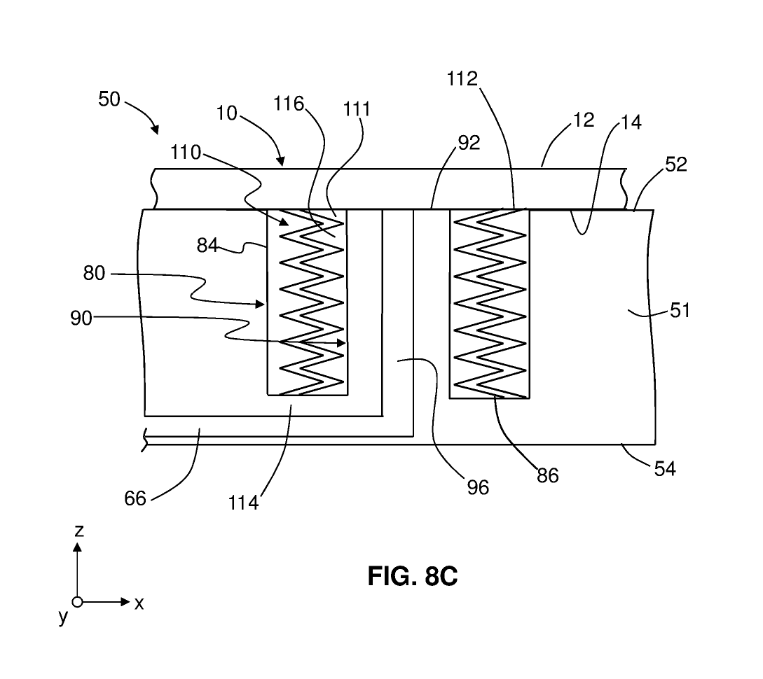

FIGS. 8A through 8C are close-up x-z cross-sectional views of chuck 50 showing the details of a third example embodiment of sealing device 100 in two different operating positions. Sealing device 100 of FIGS. 8A through 8C is similar that shown in FIGS. 5A through 5C but wherein sealing member 110 also serves as resilient member 140. Further, there is no need for support member 130.

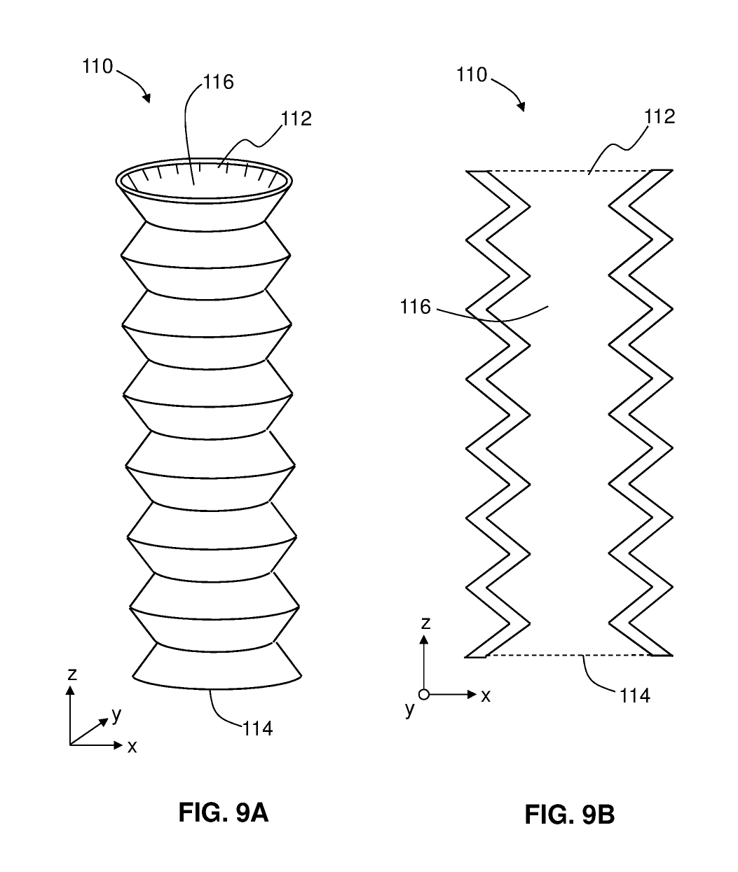

In an example, sealing member 110 is in the form of a tubular bellows, as shown in the side elevated and x-z cross-sectional views of FIGS. 9A and 9B, respectively. Sealing member 110 is open at a top end 112 and at a bottom end 114. Sealing member 110 has an interior 116 sized to accommodate central pillar 90. The tubular bellows compresses when subjected to the weight of wafer 10 and the force generated by the low internal pressure of sealing member 110. In an example, the stiffness of the tubular bellows is selected so that its compression is controlled, e.g., does not simply collapse under the weight of wafer 10.

With reference to FIG. 8A, sealing member 110 resides in recess 80 with central pillar 90 extending into interior 116 from open bottom end 114. Open top end 112 resides above the plane of upper surface 52 of chuck 50 by the height H in anticipation of receiving wafer 10. In an example, open bottom end 114 is sealed to bottom wall 86.

Since wafer 10 is still not yet in contact with sealing device 100, sealing member 110 is in an extended position (i.e., is in an extended state) within recess 80. Meanwhile, vacuum pump 70 is operating to pull a vacuum through vacuum line system 66, which as noted above is pneumatically connected to vacuum channel 96 of central pillar 90. Thus, there is a vacuum at open top end 112 of sealing member 110 via vacuum channel 96.

With reference now to FIG. 8B, wafer 10 is then lowered onto the plurality of sealing devices 100 of chuck 50, e.g., through the use of the aforementioned wafer support and handling apparatus. In an example, at least three sealing devices 100 are employed. Each sealing device 100 receives a respective portion of backside 14 of wafer 10 at sealing member 110. Backside 14 of wafer 10 is then sealed to sealing member 110 at open top end 112 by the vacuum provided by vacuum channel 96, thereby forming localized low-pressure sealed region 111, which in the present embodiment is defined by backside 14 of wafer 10, sealing member 110 and top surface 92 of pillar 90. At this point in the process, wafer 10 can still be substantially supported by the wafer support and handling apparatus.

With reference now to FIG. 8C, once wafer 10 is secured to sealing devices 100, the wafer then lowered onto upper surface 52 of chuck 50, e.g., by allowing more of the weight of the wafer to rest upon the sealing devices. This can be done simply by controlled lowering of wafer 10 using the wafer handler. During this time, sealing member 110 compresses (i.e., moves to a contracted state) so that top end 112 moves in the z-direction, i.e., downwards towards recess 80. Sealing devices 100, which are now engaged with respective portions of backside 14 of wafer 10, guide the wafer down to upper surface 52 of chuck 50. Vacuum features 60 (FIG. 1A) further engage backside 14 of wafer 10 to hold the wafer onto upper surface 52 of chuck 50. Note that top surface 92 of central pillars 90 also support backside 14 of wafer 10 when sealing devices 100 are in their contracted operating positions wherein height H=0.

Thus, as in the first and second embodiments, in the first stage, sealing devices 100 engage respective portions of backside 14 of wafer 10 while the wafer is still outside of the vacuum range of vacuum features 60 and while the sealing devices 100 are in their extended operating position. In the second stage, sealing devices 100 are used to control the landing of wafer 10 onto upper surface 52 of chuck 50 so that the full vacuum of vacuum line system 66 can be employed to chuck the wafer via vacuum features 60. Localized low-pressure sealed regions 111 defined by sealing devices 100 reach higher above upper surface 52 of chuck 50 than conventional ring seals. In the third stage, sealing devices 100 are in their contracted operating position wherein H=0. In this third example embodiment, sealing device 100 does require support member 130 and resilient member 140 used in the other embodiments.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A wafer chuck apparatus for chucking a wafer having a backside, comprising:
a chuck having a body and an upper surface, including at least one recess formed in the body at the upper surface, and a plurality of vacuum features open to the upper surface of the body;
a vacuum line system formed within the body of the chuck and that is pneumatically connected to the vacuum features, to the at least one recesses, and to a vacuum pump;
at least one sealing device operably disposed in the at least one recess and in pneumatic communication with the vacuum line system, wherein the at least one sealing device has a top end and is contractible between an expanded operating position and a contracted operating position, and wherein a sealing member defines the top end and is configured to form a vacuum seal with a portion of the backside of the wafer; and
wherein the top end extends to a height H above the upper surface of the body of the chuck in the expanded operating position wherein the height H is in the range of 2 mm≤H≤6 mm, and wherein the at least one sealing device contracts from the expanded operating position to the contracted operating position wherein H=0 when the backside of the wafer is disposed upon and forms the vacuum seal with the at least one sealing device and the vacuum features.

2. The wafer chuck apparatus according to claim 1, wherein the sealing member is resilient and contracts to a contracted state to define the contracted operating position.

3. The wafer chuck apparatus according to claim 1, wherein the sealing member comprises a tubular bellows.

4. The wafer chuck apparatus according to claim 3, wherein the tubular bellows has an interior and a bottom end, the recess includes a pillar with a top surface and a vacuum channel open at the top end of the at least one sealing device and pneumatically connected to the vacuum line system, and wherein the pillar extends into the interior of the tubular bellows from the bottom end of the tubular bellows, and wherein the top surface of the pillar is co-planar with the upper surface of the chuck.

5. The wafer chuck apparatus according to claim 1, further comprising:
a support member that supports the sealing member; and
a resilient member that supports the support member, wherein the resilient member has an extended state that defines the extended operating position and has a contracted state that defines the contracted operating position.

6. The wafer chuck apparatus according to claim 5, wherein the recess includes a pillar with a top surface and a vacuum channel open at the top end of the at least one sealing device and pneumatically connected to the vacuum line system, and wherein the support member includes a central hole, wherein the pillar extends into the central hole of the support member, and wherein the top surface of the pillar is co-planar with the upper surface of the chuck.

7. The wafer chuck apparatus according to claim 6, wherein the support member has a donut shape.

8. The wafer chuck apparatus according to claim 1, wherein the sealing member comprises a gasket.

9. The wafer chuck apparatus according to claim 1, wherein the sealing member comprises an O-ring.

10. The wafer chuck apparatus according to claim 1, wherein the at least one sealing device comprises three or more sealing devices.

11. The wafer chuck apparatus according to claim 1, wherein at least one sealing device comprises at least three and no more than twelve sealing devices.

12. A wafer chuck apparatus for chucking a wafer having a backside, comprising:
a chuck having a body and an upper surface, including at least three recesses formed in the body at the upper surface, and a plurality of vacuum holes open to the upper surface of the body;
a vacuum line system formed within the body of the chuck and that is pneumatically connected to the vacuum holes, to each of the recesses, and to a vacuum pump;
at least three contractible sealing devices respectively operably disposed in the at least three recesses and in pneumatic communication with the vacuum line system, wherein each contractible sealing device has an expanded operating position and a contracted operating position and comprises:
i) a top end that resides at a height H above the upper surface of the body of the chuck in the expanded operating position, wherein the height H is in the range of 2 mm≤H≤6 mm;
ii) a sealing member that defines the top end and that is configured to form a localized vacuum seal with a portion of the backside of the wafer when the wafer is brought into contact with the sealing member;
iii) a support member having opposite top and bottom surfaces, wherein the top surface supports the sealing member and wherein a vacuum channel passes through the support member and is in pneumatic communication with the vacuum line system; and
iv) a resilient member in contact with the bottom surface of the support member also in contact with a bottom wall of the recesses, the resilient member being in an expanded state in the expanded operating position and a contracted state in the contracted operating position; and
wherein each contractible sealing device is configured to move from the expanded operating position to the contracted operating position wherein H=0 when the wafer is disposed upon and supported by the at least three contractible sealing devices.

13. The wafer chuck apparatus according to claim 12, wherein the sealing member comprises one of a gasket, an O-ring or a bellows.

14. The wafer chuck apparatus according to claim 12, wherein the resilient member comprises as least one spring.

15. The wafer chuck apparatus according to claim 12, wherein the sealing member has a central aperture, and wherein the recess includes a pillar with a top surface, with the vacuum channel passing through the pillar and open at the top end and pneumatically connected to the vacuum line system, and wherein the pillar extends into the central aperture of the sealing member.

16. The wafer chuck apparatus according to claim 15, wherein the top surface of the pillar is co-planar with the upper surface of the chuck.

17. A method of chucking a wafer having a backside and a first amount of warp onto an upper surface of a chuck, comprising:
a) pneumatically engaging respective portions of the backside of the wafer with a plurality of contractible sealing devices that reside in respective recesses formed in the upper surface of the chuck and that initially extend above the upper surface of the chuck by an initial height H in the range of 2 mm≤H≤6 mm to cause the wafer to have a second amount of warp that is less than the first amount of warp;
b) contracting the plurality of contractible sealing devices into their respective recesses to bring the wafer down to the upper surface of the chuck so that the height H=0; and
c) pneumatically engaging the backside of the wafer at the upper surface of the chuck to cause the wafer to have a third amount of warp than is less than the second amount of warp.

18. The method according to claim 17, wherein each contractible sealing device comprises a tubular bellows having an open top side that forms a vacuum seal with corresponding respective portions of the backside of the wafer in act a), and wherein the act b) of contracting includes compressing the tubular bellows.

19. The method according to claim 17, wherein the plurality of contractible sealing devices comprises at least three and no more than twelve contractible sealing devices.

20. The method according to claim 17, wherein each contractible sealing device includes a sealing member supported by a spring, and wherein the act b) of contracting includes compressing the spring.

21. The method according to claim 20 wherein a support member resides between the sealing member and the spring.

22. The method according to claim 17, wherein the wafer has a weight, and wherein the act b) of contracting is caused by the weight of the wafer.
